(19) United States
(12) Patent Application Publication
(10) Pub. No.: US 2025/0285680 A1
(43) Pub. Date: Sep. 11, 2025

(54) SEMICONDUCTOR MEMORY DEVICE, OPERATING METHOD OF THE SAME, AND ELECTRONIC SYSTEM INCLUDING THE SAME

(71) Applicant: Samsung Electronics Co., Ltd., Suwon-si (KR)

(72) Inventors: Kwang-Soo KIM, Suwon-si (KR); Tae Young KIM, Suwon-si (KR); Su Hwan LIM, Suwon-si (KR)

(73) Assignee: Samsung Electronics Co., Ltd., Suwon-si (KR)

(21) Appl. No.: 19/008,118

(22) Filed: Jan. 2, 2025

(30) Foreign Application Priority Data
Mar. 5, 2024 (KR) 10-2024-0031457

(51) Int. Cl. G11C 16/10; G11C 16/04; G11C 16/08; G11C 16/24; H01L 25/065; H10B 41/27; H10B 41/35; H10B 43/27; H10B 43/35

(52) U.S. Cl. CPC G11C 16/10; G11C 16/0483; G11C 16/08; G11C 16/24; H01L 25/0657; H01L 2225/06562; H10B 41/27; H10B 41/35; H10B 43/27; H10B 43/35

(57) ABSTRACT

There are provided a semiconductor memory device including a ferroelectric-based data storage element, a programming method thereof, and an electronic system. The programming method of a semiconductor memory device which includes a plurality of word lines stacked to be spaced apart from each other in a vertical direction, a channel pattern that extends in the vertical direction and intersects the plurality of word lines, and a data storage pattern including ferroelectrics between the plurality of word lines and the channel pattern, the programming method comprising, performing an initializing operation on a plurality of memory cells corresponding to the plurality of word lines, by applying a positive (+) voltage to the plurality of word lines or by applying a negative (−) voltage to the channel pattern, and performing a program operation on a target memory cell corresponding to a selected word line, by applying a negative (−) program voltage to the selected word line among the plurality of word lines, after performing the initializing operation.

### CROSS-REFERENCE TO RELATED APPLICATION

This application claims priority from Korean Patent Application No. 10-2024-0031457 filed on Mar. 5, 2024 in the Korean Intellectual Property Office, and all the benefits accruing therefrom under 35 U.S.C. 119, the contents of which in its entirety are herein incorporated by reference.

### BACKGROUND

Various example embodiments relate to a semiconductor memory device, a programming method thereof, and an electronic system including the same. More specifically, various example embodiments relate to a semiconductor memory device including a ferroelectric-based data storage element, a programming method thereof, and an electronic system including the same.

As the semiconductor memory device capable of storing high-capacity data is desired in an electronic system, schemes for increasing the data storage capacity of the semiconductor memory device are being researched. As one of schemes for increasing the data storage capacity of the semiconductor memory device, a semiconductor memory device including memory cells arranged three-dimensionally instead of memory cells arranged two-dimensionally has been proposed.

### SUMMARY

Various example embodiments provide a semiconductor memory device having improved performance and reliability.

Various example embodiments also provide a programming method of the semiconductor memory device having improved performance and reliability.

Various example embodiments also provide an electronic system including a semiconductor memory device having improved performance and reliability.

However, various example embodiments are not restricted to the one set forth herein. The above example embodiments and other aspects of the present disclosure will become more apparent to one of ordinary skill in the art to which the present disclosure pertains by referencing the detailed description of various example embodiments given below.

According to various example embodiments, there is provided a programming method of a semiconductor memory device which includes a plurality of word lines stacked to be spaced apart from each other in a vertical direction, a channel pattern that extends in the vertical direction and intersects the plurality of word lines, and a data storage pattern including ferroelectrics between the plurality of word lines and the channel pattern, the programming method comprising, performing an initializing operation on a plurality of memory cells corresponding to the plurality of word lines, by applying a positive (+) voltage to the plurality of word lines or by applying a negative (−) voltage to the channel pattern, and performing a program operation on a target memory cell corresponding to a selected word line, by applying a negative (−) program voltage to the selected word line among the plurality of word lines, after performing the initializing operation.

According to various example embodiments, there is provided a programming method of a semiconductor memory device which includes a plurality of word lines stacked to be spaced apart from each other in a vertical direction, a channel pattern that extends in the vertical direction and intersects the plurality of word lines, and a data storage pattern including ferroelectrics between the plurality of word lines and the channel pattern, the programming method comprising, performing an initializing operation on a plurality of memory cells corresponding to the plurality of word lines, and performing a first program operation on a target memory cell corresponding to a selected word line, by applying a negative (−) first program voltage to the selected word line among the plurality of word lines, after performing the initializing operation, wherein a first threshold voltage of the target memory cell due to the first program operation is greater than an initial threshold voltage of the target memory cell due to the initializing operation.

According to various example embodiments, there is provided a semiconductor memory device comprising, a plurality of word lines stacked to be spaced apart from each other in a vertical direction, a channel pattern which extends in the vertical direction and intersects the plurality of word lines, a data storage pattern including ferroelectrics between the plurality of word lines and the channel pattern, and a control circuit electrically connected to the plurality of word lines and the channel pattern, wherein the control circuit is configured to perform an initializing operation on a plurality of memory cells corresponding to the plurality of word lines, by applying a positive (+) voltage to the plurality of word lines or by applying a negative (−) voltage to the channel pattern, and perform a program operation on a target memory cell corresponding to a selected word line, by applying a negative (−) program voltage to the selected word line among the plurality of word lines, after performing the initializing operation.

It should be noted that the effects of various example embodiments are not limited to those described above, and other effects of the present disclosure will be apparent from the following description.

### BRIEF DESCRIPTION OF THE DRAWINGS

The above and other aspects and features of various example embodiments will become more apparent by describing in detail illustrative embodiments thereof with reference to the attached drawings, in which:

FIG. 1 is an example block diagram for explaining a semiconductor memory device according to some example embodiments.

FIG. 2 is an example circuit diagram of the semiconductor memory device according to some example embodiments.

FIG. 3 is a schematic layout diagram for explaining a semiconductor memory device according to some example embodiments.

FIG. 4 is a cross-sectional view taken along line A-A of FIG. 3.

FIG. 5 is an enlarged view of a region S1 of FIG. 4.

FIG. 6 is a diagram for explaining an initializing operation of the programming method of the semiconductor memory device according to some example embodiments.

FIG. 7 is a diagram for explaining a program operation of the programming method of the semiconductor memory device according to some example embodiments.

FIG. 8 is a graph for explaining a threshold voltage distribution of the semiconductor memory device according to some example embodiments.

FIG. 9 is a timing diagram for explaining a program operation of the programming method of the semiconductor memory device according to some example embodiments.

FIGS. 10 and 11 are graphs for explaining the effects of the programming method of the semiconductor memory device according to some example embodiments.

FIG. 12 is a schematic cross-sectional view for explaining a semiconductor memory device according to some example embodiments.

FIG. 13 is an enlarged view for explaining a region R2 of FIG. 12.

FIG. 14 is a schematic cross-sectional view for explaining a semiconductor memory device according to some example embodiments.

FIG. 15 is an enlarged view for explaining a region R3 of FIG. 14.

FIG. 16 is an example block diagram for explaining an electronic system according to some example embodiments.

FIG. 17 is an example perspective view for explaining the electronic system according to some example embodiments.

FIG. 18 is a schematic cross-sectional view taken along I-I of FIG. 17.

### DETAILED DESCRIPTION OF THE EMBODIMENTS

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of various example embodiments.

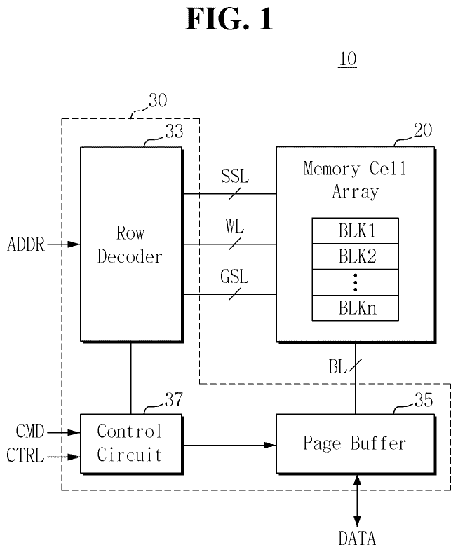

Hereinafter, a semiconductor memory device according to various example embodiments will be described with reference to FIGS. 1 to 5.

FIG. 1 is an example block diagram for explaining a semiconductor memory device according to some example embodiments.

A memory cell array 20 may include a plurality of memory cell blocks BLK1 to BLKn. Each of the memory cell blocks BLK1 to BLKn may include a plurality of memory cells. The memory cell array 20 may be connected to a peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL, and the ground selection line GSL. Also, the memory cell blocks BLK1 to BLKn may be connected to a page buffer 35 through the bit line BL.

The peripheral circuit 30 may receive an address ADDR, a command CMD, and a control signal CTRL from the outside of the semiconductor memory device 10, and may transmit and receive data DATA to and from an external device of the semiconductor memory device 10. The peripheral circuit 30 may include a control circuit 37, a row decoder 33, and a page buffer 35. Although it is not shown, the peripheral circuit 30 may further include various sub-circuits such as an I/O circuit, a voltage generation circuit that generates various voltages necessary for the operation of the semiconductor memory device 10, and an error correction circuit for correcting an error of the data DATA that is read from the memory cell array 20.

The control circuit 37 may be connected to the row decoder 33, the I/O circuit, and the voltage generation circuit. The control circuit 37 may control the overall operation of the semiconductor memory device 10. The control circuit 37 may generate various internal control signals used inside the semiconductor memory device 10 in response to the control signal CTRL. For example, the control circuit 37 may adjust the voltage levels provided to the word line WL and the bit line BL, when performing a memory operation such as a program operation or an erasing operation.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks BLK1 to BLKn. Further, the row decoder 33 may transmit a voltage for performing the memory operation to the word line WL of the selected memory cell blocks BLK1 to BLKn.

The page buffer 35 may be connected to the memory cell array 20 through the bit line BL. The page buffer 35 may operate as a writer driver or a sense amplifier. Specifically, when performing the program operation, the page buffer 35 may operate as the writer driver to apply the voltage according to the data DATA to be stored in the memory cell array 20 to the bit line BL. On the other hand, when performing the read operation, the page buffer 35 may operate as the sense amplifier to sense the data DATA stored in the memory cell array 20.

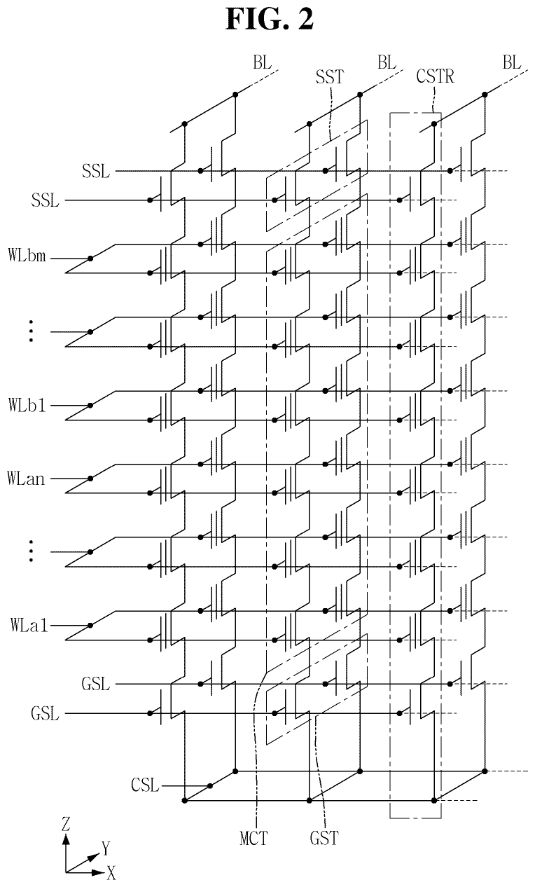

FIG. 2 is an example circuit diagram of the semiconductor memory device according to some example embodiments.

Referring to FIG. 2, a memory cell array (e.g., 20 of FIG. 1) of the semiconductor memory device according to some example embodiments may include a common source line CSL, a plurality of bit lines BL, and a plurality of cell strings CSTR.

The plurality of bit lines BL may be arranged two-dimensionally in a plane including a first direction X and a second direction Y. For example, the bit lines BL each extend in the second direction Y, may be spaced apart from each other, and may be arranged along the first direction X. A plurality of cell strings CSTR may be connected in parallel to each bit line BL. The cell strings CSTR may be commonly connected to the common source line CSL. That is, a plurality of cell strings CSTR may be disposed between the bit lines BL and the common source line CSL.

Each cell string CSTR may include a ground selection transistor GST connected to the common source line CSL, a string selection transistor SST connected to the bit line BL, and a plurality of memory cell transistors MCT disposed between the ground selection transistor GST and the string selection transistor SST. Each memory cell transistor MCT may include a data storage element. The ground selection transistor GST, the string selection transistor SST, and the memory cell transistors MCT may be connected in series in a vertical direction (hereinafter, a third direction Z) that intersects the first direction X and the second direction Y.

The common source line CSL may be commonly connected to the sources of the ground selection transistors GST. Also, a ground selection line GSL, a plurality of word lines WLal to WLan and WLb1 to WLbm, and a string selection line SSL may be disposed between the common source line CSL and the bit line BL. The ground selection line GSL may be used as a gate electrode of the ground selection transistor GST, the word lines WLal to WLan and WLb1 to WLbm may be used as the gate electrodes of the memory cell transistors MCT, and the string selection line SSL may be used as the gate electrode of the string selection transistor SST.

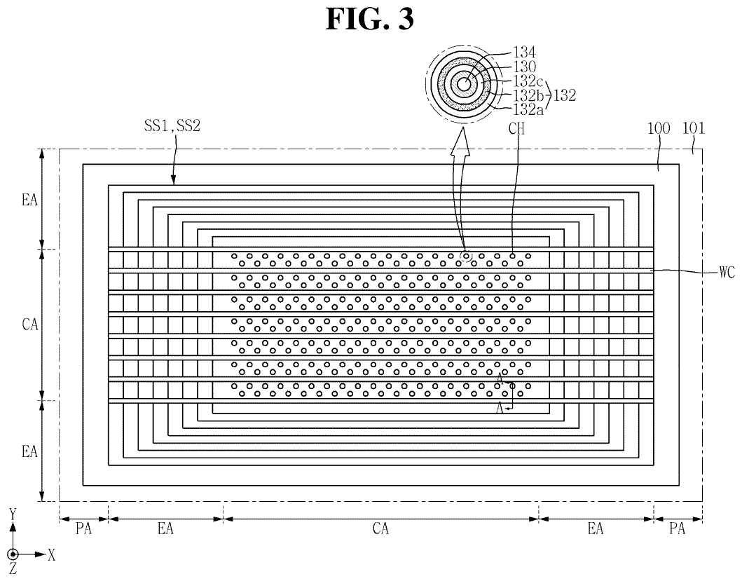

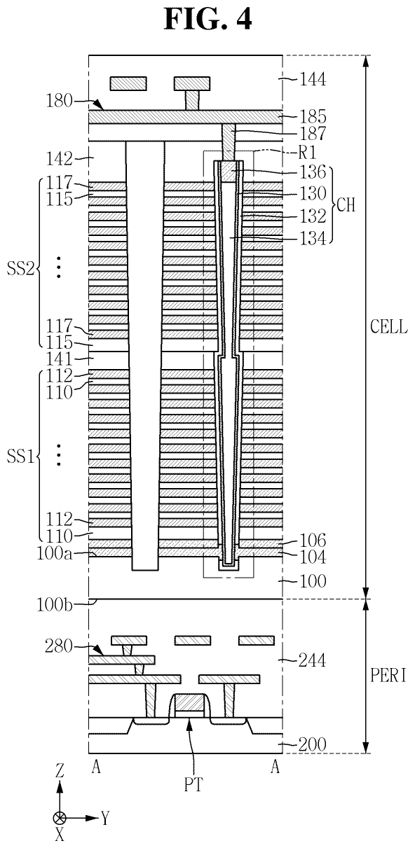

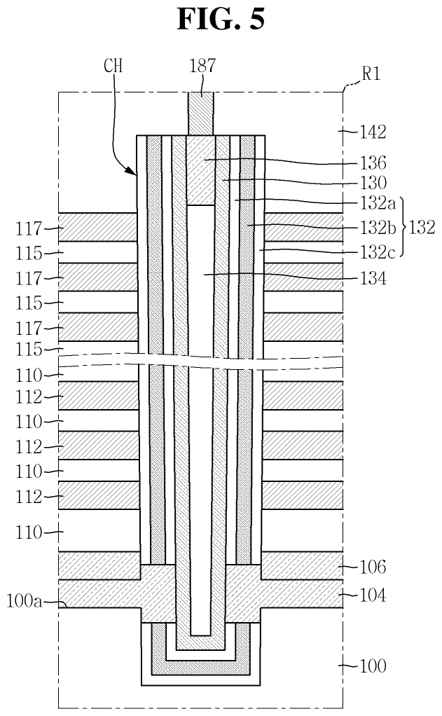

FIG. 3 is a schematic layout diagram for explaining a semiconductor memory device according to some example embodiments. FIG. 4 is a cross-sectional view taken along line A-A of FIG. 3. FIG. 5 is an enlarged view of a region S1 of FIG. 4.

Referring to FIGS. 3 to 5, the semiconductor memory device according to some example embodiments includes a memory cell structure CELL and a peripheral circuit structure PERI.

The memory cell structure CELL may include a cell array region CA, an extension region EA, and an external region PA.

A memory cell array (e.g., 20 of FIG. 1) including a plurality of memory cells may be formed in the cell array region CA. For example, a source layer 104, gate electrodes 112 and 117, a channel structure CH, a conductive line 185, and the like, which will be described below, may be disposed in the cell array region CA.

The extension region EA may be disposed around the cell array region CA. For example, the extension region EA may be adjacent to the cell array region CA in the first direction X. The gate electrodes 112 and 117, which will be described below, may be stacked in the extension region EA in a stepped shape.

The external region PA may be a peripheral region that surrounds the cell array region CA and the extension region EA. For example, the external region PA may be adjacent to the cell array region CA and/or the extension region EA in the first direction X and/or the second direction Y.

The memory cell structure CELL may include a first substrate 100, stacked structures SS1 and SS2, interlayer insulating films 141 and 142, a channel structure CH, a cutting pattern WC, and a first wiring structure 180.

The first substrate 100 may include, for example, a semiconductor substrate, such as a silicon substrate, a germanium substrate, or a silicon-germanium substrate. Alternatively, the first substrate 100 may include a silicon-on-insulator (SOI) substrate, a germanium-on-insulator (GOI) substrate, or the like. However, example embodiments are not limited thereto.

The first substrate 100 may include a first side 100a and a second side 100b that are opposite to each other. The first side 100a and the second side 100b may each extend along a horizontal plane (e.g., an XY plane). In the following description, the first side 100a may also be referred to as a front side of the first substrate 100, and the second side 100b may also be referred to as a back side of the first substrate 100.

The stacked structures SS1 and SS2 may be disposed inside the cell array region CA and the extension region EA. The stacked structures SS1 and SS2 may be formed on the first side 100a of the first substrate 100. The stacked structures SS1 and SS2 may include a plurality of mold insulating films 110 and 115 and a plurality of gate electrodes 112 and 117 that are stacked on the first substrate 100. Each of the mold insulating films 110 and 115 and each of the gate electrodes 112 and 117 may have a layered structure extending along a horizontal plane (e.g., an XY plane). The gate electrodes 112 and 117 may be spaced apart from each other by the mold insulating films 110 and 115 and stacked one after another.

In some example embodiments, the stacked structures SS1 and SS2 include the plurality of gate stacks (e.g., a first gate stack SS1 and a second gate stack SS2) that are stacked sequentially on the first substrate 100. Although the number of stacks stacked on the first substrate 100 is only shown as being two, this is only an example, and the number of gate stacks stacked on the first substrate 100 may, of course, be three or more.

The first gate stack SS1 may include first mold insulating films 110 and first gate electrodes 112 that are alternately stacked on the first substrate 100. In some example embodiments, the first gate electrodes 112 may include at least one ground selection line (e.g., GSL of FIG. 2) and a plurality of first word lines (e.g., WLal to WLan of FIG. 2) that are stacked sequentially on the first substrate 100. The number, shape, and the like of the first mold insulating films 110 and the first gate electrodes 112 are merely examples, and are not limited to those shown.

The second gate stack SS2 may include second mold insulating films 115 and second gate electrodes 117, which are alternately stacked on the first gate stack SS1. In some example embodiments, the second gate electrodes 117 may include a plurality of second word lines (e.g., WLb1 to WLbm of FIG. 2) and at least one string selection line (e.g., SSL of FIG. 2) that are stacked sequentially on the first gate stack SS1. The number, shape, and the like of the second mold insulating films 115 and the second gate electrodes 117 are merely examples, and are not limited to those shown.

The gate electrodes 112 and 117 may each include a conductive material, for example, but not limited to, a metal such as tungsten (W), molybdenum (Mo), ruthenium (Ru), cobalt (Co), or nickel (Ni), or a semiconductor material such as silicon. As an example, the gate electrodes 112 and 117 may each include at least one of tungsten (W), molybdenum (Mo), and ruthenium (Ru). As another example, the gate electrodes 112 and 117 may each include polysilicon. However, example embodiments are not limited thereto.

In some example embodiments, each of the gate electrodes 112 and 117 may include a barrier metal film and a filler metal film that are stacked in sequence. The barrier metal film may include, for example, a metal nitride film such as titanium nitride (TiN). However, example embodiments are not limited thereto. The filling metal film may fill the regions of the gate electrode 112 and 117 that remain after the barrier metal film is filled.

Each of the mold insulating films 110 and 115 may include, for example, but not limited to, at least one of silicon oxide, silicon nitride, and silicon oxynitride. As an example, the mold insulating films 110 and 115 may each include a silicon oxide film.

The interlayer insulating films 141 and 142 may be formed on the first side 100a of the first substrate 100 to cover the stacked structures SS1 and SS2. For example, a first interlayer insulating film 141 may be formed on the first substrate 100 to cover the first gate stack SS1, and a second interlayer insulating film 142 may be formed on the first interlayer insulating film 141 to cover the second gate stack SS2. The interlayer insulating films 141 and 142 may include, for example, but not limited to, at least one of silicon oxide, silicon oxynitride, and a low-k material having a dielectric constant lower than that of silicon oxide.

The channel structure CH may be disposed inside the cell array region CA. The channel structure CH may extend in the vertical direction (e.g., a third direction Z) and intersect the plurality of gate electrodes 112 and 117. For example, the channel structure CH may extend in the third direction Z and penetrate the stacked structures SS1 and SS2. The channel structure CH may be a pillar (e.g., cylindrical) structure extending in the third direction Z.

In some example embodiments, the plurality of channel structures CH may be arranged in the form of a zigzag. For example, as shown in FIG. 3, the channel structures CH may be arranged alternately in the first direction X and the second direction Y. Such channel structures CH may further improve the degree of integration of the semiconductor memory device. The number, placement, and the like of the channel structures CH are merely examples and are not limited to those shown.

In some example embodiments, each channel structure CH may have a step between the first gate stack SS1 and the second gate stack SS2. For example, as shown in FIG. 4, the side surface of each channel structure CH may have a bending portion at a boundary between the first interlayer insulating film 141 and the second gate stack SS2.

The channel structure CH may include a channel pattern 130 and a data storage pattern 132.

The channel pattern 130 may extend in the third direction Z and intersect the plurality of gate electrodes 112 and 117. Although the channel pattern 130 is only shown to have a cup shape, this is only an example. For example, the channel pattern 130 may have various shapes such as a cylindrical shape, a square tube shape, a solid filler shape, and the like. The channel pattern 130 may include semiconductor materials such as, but not limited to, single crystal silicon, polycrystalline silicon, organic semiconductor substance, and carbon nanostructure.

The data storage pattern 132 may be interposed between the channel pattern 130 and the plurality of gate electrodes 112 and 117. For example, the data storage pattern 132 may extend conformally along the profile of the outer side surface of channel pattern 130.

The data storage pattern 132 may include ferroelectrics. The ferroelectrics have polarization, and a direction of polarization may change by an external electric field, and may have remnant polarization due to a dipole even in the absence of an external electric field. Each memory cell may store data, by using the polarization state of the data storage pattern 132.

In some example embodiments, the data storage pattern 132 may include a first insulating film 132a, a ferroelectric film 132b, and a second insulating film 132c, which are sequentially stacked on the outer side surface of the channel pattern 130.

The first insulating film 132a may be interposed between the channel pattern 130 and the ferroelectric film 132b. For example, the first insulating film 132a may conformally extend along the profile of the outer side surface of the channel pattern 130. The first insulating film 132a may include, for example, at least one of silicon oxide, silicon nitride, silicon oxynitride, or a high dielectric constant material having a higher dielectric constant than silicon oxide (e.g., aluminum oxide (Al₂O₃) and hafnium oxide (HfO₂)) and combinations thereof. However, example embodiments are not limited thereto. As an example, the first insulating film 132a may include a silicon oxide film. In some example embodiments, the first insulating film 132a may be omitted.

The ferroelectric film 132b may be interposed between the first insulating film 132a and the second insulating film 132c. For example, the ferroelectric film 132b may extend conformally along the profile of the outer side surface of the first insulating film 132a. The ferroelectric film 132b may include, for example, but not limited to, at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof.

The second insulating film 132c may be interposed between the ferroelectric film 132b and the gate electrodes 112 and 117. For example, the second insulating film 132c may extend conformally along the profile of the outer side surface of the ferroelectric film 132b. The second insulating film 132c may include, for example, at least one of silicon oxide, silicon nitride, silicon oxynitride, a high dielectric constant material having a higher dielectric constant than silicon oxide (e.g., aluminum oxide (Al₂O₃) or hafnium oxide (HfO₂)), and combinations thereof. As an example, the second insulating film 132c may include a silicon oxide film. In some example embodiments, the second insulating film 132c may be omitted.

In some example embodiments, the channel structure CH may further include a filling insulating film 134. The filling insulating film 134 may be formed to fill the inside of the cup-shaped channel pattern 130. The filling insulating film 134 may include an insulating material, for example, but not limited to, silicon oxide.

In some example embodiments, the channel structure CH may further include a channel pad 136. The channel pad 136 may be formed to be connected to one end (e.g., the upper end) of the channel pattern 130. The channel pad 136 may include a conductive material, for example, but not limited to, impurity-doped polysilicon, metal, metal silicide or the like. As an example, the channel pad 136 may include a polysilicon film doped with an N-type impurity (e.g., phosphorus (P) or arsenic (As)). However, example embodiments are not limited thereto.

In some example embodiments, a source layer 104 and a source support layer 106 may be formed between the first substrate 100 and the stacked structures SS1 and SS2.

The source layer 104 may extend along the first side 100a of the first substrate 100. The source layer 104 may be electrically connected to the channel pattern 130. For example, the source layer 104 may penetrate the data storage pattern 132 and may be in contact with the side surfaces of the channel pattern 130.

The source layer 104 may include a conductive material, for example, but not limited to, impurity-doped polysilicon or metal. As an example, the source layer 104 may include a polysilicon film doped with an N-type impurity (e.g., phosphorus (P) or arsenic (As)). The first substrate 100 and the source layer 104 may be provided as a common source line (e.g., CSL of FIG. 2) of the semiconductor memory device according to some example embodiments.

The source support layer 106 may be formed on the first substrate 100 and the source layer 104. For example, the source support layer 106 may extend along the upper surface of the source layer 104. The source support layer 106 may be used as a support for limiting or preventing the mold stack from collapsing or falling in a replacement process for forming the source layer 104. The source support layer 106 may include, for example, but not limited to, a polysilicon film. In some example embodiments, the first substrate 100, the source layer 104, and the source support layer 106 may be provided as a common source line (e.g., CSL of FIG. 2) of the semiconductor memory device.

The cutting pattern WC may be formed over the cell array region CA and the extension region EA. The cutting pattern WC may extend long in the first direction X to cut the stacked structures SS1 and SS2. Further, the plurality of cutting patterns WC each extend in the first direction X, are spaced apart from each other, and may be arranged along the second direction Y. The stacked structures SS1 and SS2 may be divided by a plurality of cutting patterns WC to form a plurality of memory cell blocks (e.g., BLK1 to BLKn of FIG. 1). For example, two adjacent cutting patterns WC may define one memory cell block between them. A plurality of channel structures CH may be disposed inside each memory cell block defined by the cutting patterns WC.

In some example embodiments, the cutting pattern WC may include an insulating material, for example, but not limited to, at least one of silicon oxide, silicon nitride, and/or silicon oxynitride. For example, the cutting pattern WC may include a silicon oxide film.

The first wiring structure 180 may be formed on the second interlayer insulating film 142. The first wiring structure 180 may be electrically connected to the source layer 104, the gate electrodes 112 and 117, and/or the channel structure CH. For example, a first inter-wiring insulating film 144 may be formed on the second interlayer insulating film 142. The first wiring structure 180 is formed inside the first inter-wiring insulating film 144, and may be connected to the source layer 104, the gate electrodes 112 and 117, and/or the channel structure CH. The number of layers, placement, and the like of the first wiring structure 180 are merely examples, and are not limited to those shown.

The first wiring structure 180 may include a conductive material, for example, but not limited to, at least one of aluminum (Al), copper (Cu), tungsten (W), molybdenum (Mo), cobalt (Co), ruthenium (Ru), and an alloy thereof.

In some example embodiments, the first wiring structure 180 may include a conductive line 185 disposed inside the cell array region CA. The conductive line 185 may extend long in the second direction Y. Furthermore, the plurality of conductive lines 185 each extend in the second direction Y, are spaced apart from each other, and may be arranged along the first direction X.

The conductive line 185 may be electrically connected to the plurality of channel structures CH arranged along the second direction Y. For example, a channel contact 187 that extends in the third direction Z to connect the channel pad 136 and the conductive line 185 may be formed. The conductive line 185 may be connected to one end (e.g., the upper end) of the channel pattern 130 through the channel contact 187 and the channel pad 136. Such a conductive line 185 may be provided as a bit line (e.g., BL of FIG. 2) of the semiconductor memory device according to some example embodiments.

The peripheral circuit structure PERI may include a second substrate 200, a peripheral circuit element PT, and a second wiring structure 280.

The second substrate 200 may include, for example, a semiconductor substrate, such as a silicon substrate, a germanium substrate, or a silicon-germanium substrate. However, example embodiments are not limited thereto. Alternatively, the second substrate 200 may include a silicon-on-insulator (SOI) substrate, a germanium-on-insulator (GOI) substrate, or the like.

The peripheral circuit element PT may be formed on the second substrate 200. The peripheral circuit element PT may constitute a peripheral circuit (e.g., 30 of FIG. 1) that controls the operation of the semiconductor memory device. For example, the peripheral circuitry PT may include a control circuit (e.g., 37 of FIG. 1), a row decoder (e.g., 33 of FIG. 1), a page buffer (e.g., 35 of FIG. 1), and the like. In the following description, a surface of the second substrate 200 on which the peripheral circuit elements PT are disposed may also be referred to as a front side of the second substrate 200. In contrast, a surface of the second substrate 200 opposite to the front side of the second substrate 200 may also be referred to as a back side of the second substrate 200.

The peripheral circuit element PT may include, for example, but not limited to, a transistor. For example, the peripheral circuit elements PT include not only various active elements such as a transistor, but also various passive elements such as a capacitor, a resistor, and an inductor.

The second wiring structure 280 may be formed on the peripheral circuit element PT. For example, a second inter-wiring insulating film 244 may be formed on the front side of the second substrate 200. The second wiring structure 280 is formed inside the second inter-wiring insulating film 244, and may be electrically connected to the peripheral circuit element PT. The number of layers, placement, and the like of the shown second wiring structure 280 are merely example, and are not limited those shown.

In some example embodiments, the memory cell structure CELL may be stacked on the peripheral circuit structure PERI. For example, the memory cell structure CELL may be stacked on the second inter-wiring insulating film 244.

In some example embodiments, the second side 100b of the first substrate 100 may be opposite to the peripheral circuit structure PERI. For example, the first substrate 100 may be interposed between the stacked structures SS1 and SS2 and the peripheral circuit structure PERI.

Hereinafter, a programming method of a semiconductor memory device according to an example embodiment will be described with reference to FIGS. 1 to 11. In this specification, although each memory cell included in the semiconductor memory device will be mainly described as being an N-type transistor, this is merely an example. Those skilled in the art to which various example embodiments pertain will also understand a case where each memory cell included in the semiconductor memory device is a P-type transistor. For convenience of explanation, repeated parts of those explained above using FIGS. 1 to 5 will be briefly explained or omitted.

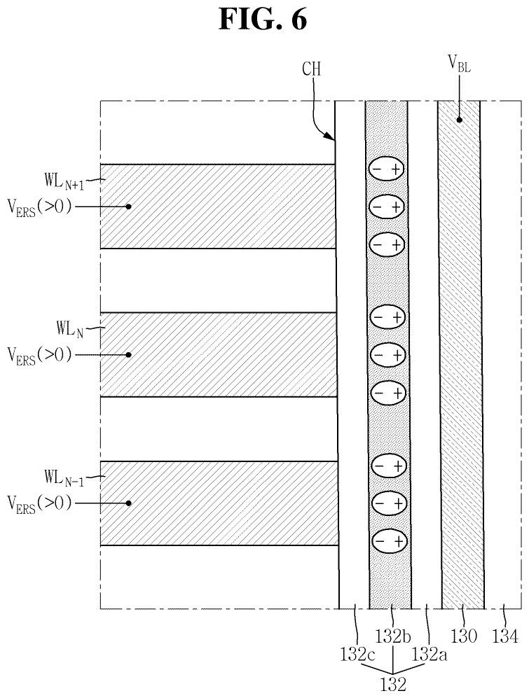

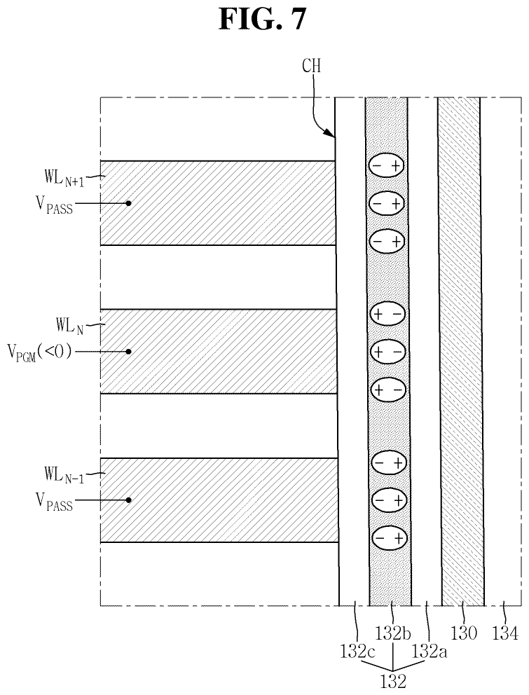

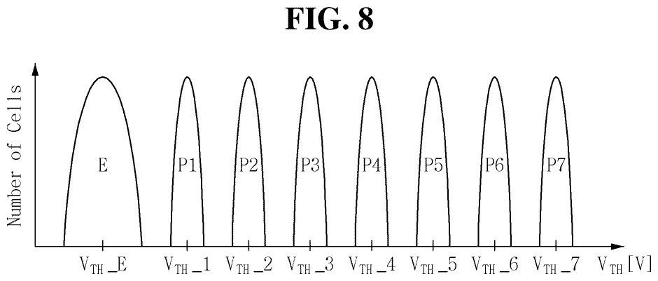

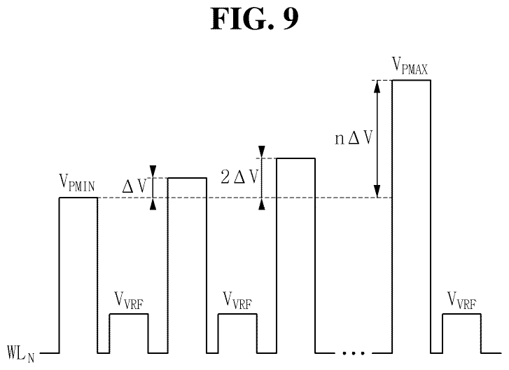

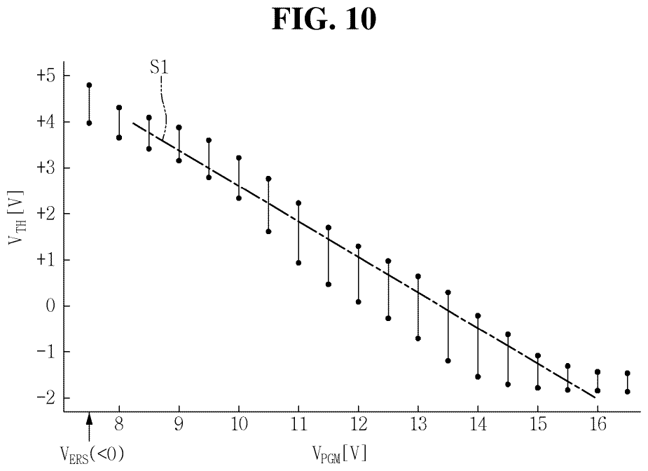

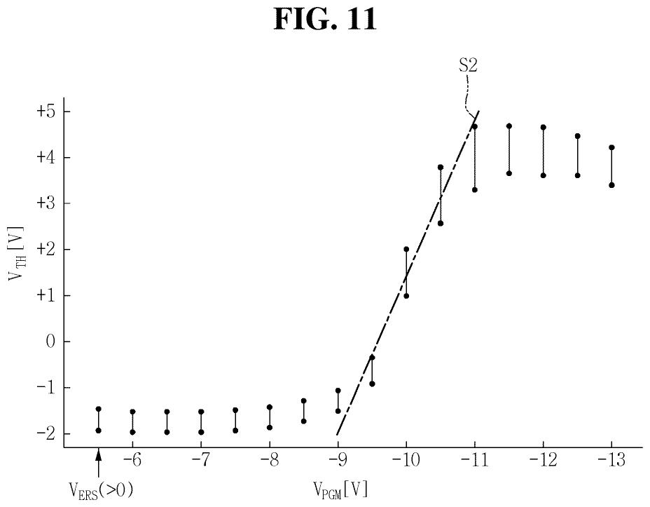

FIG. 6 is a diagram for explaining an initializing operation of the programming method of the semiconductor memory device according to some example embodiments. FIG. 7 is a diagram for explaining a program operation of the programming method of the semiconductor memory device according to some example embodiments. FIG. 8 is a graph for explaining a threshold voltage distribution of the semiconductor memory device according to some example embodiments. FIG. 9 is a timing diagram for explaining a program operation of the programming method of the semiconductor memory device according to some example embodiments. FIGS. 10 and 11 are graphs for explaining the effects of the programming method of the semiconductor memory device according to some example embodiments.

Referring to FIG. 6, an initializing operation is performed on a plurality of memory cells corresponding to a plurality of word lines WL_{N-1}, WL_{N}, and WL_{N+1}. In this specification, the initializing operation may also be referred to as an erasing operation.

At the time of the initializing operation, a positive (+) voltage may be applied to the plurality of word lines WL_{N-1}, WL_{N}, and WL_{N+1}, or a negative (−) voltage may be applied to the channel pattern 130. For example, at the time of the initializing operation, the control circuit (e.g., 37 of FIG. 1) may be configured to apply an initializing voltage V_{ERS} having a positive (+) value to the plurality of word lines WL_{N-1}, WL_{N}, and WL_{N+1}. Alternatively, for example, at the time of the initializing operation, the control circuit (e.g., 37 of FIG. 1) may be configured to apply a bit line voltage VBL having a negative (−) value to the bit line (e.g., 185 of FIG. 4) connected to the channel pattern 130.

As the initializing operation is performed, dipoles of the data storage pattern 132 may be oriented so that cathodes are located toward the word lines WL_{N-1}, WL_{N}, and WL_{N+1}, and anodes are located toward the channel pattern 130, as shown. That is, by the above initializing operation, the plurality of memory cells corresponding to the plurality of word lines WL_{N-1}, WL_{N}, and WL_{N+1} may have relatively low threshold voltages.

Referring to FIG. 7, a program operation is performed on a target memory cell corresponding to a selected word line WL_{N} among the plurality of word lines WL_{N-1}, WL_{N}, and WL_{N+1}.

At the time of the program operation, a negative (−) voltage may be applied to the selected word line WL_{N}. For example, at the time of the program operation, the control circuit (e.g., 37 of FIG. 1) may be configured to apply a program voltage V_{PGM} having a negative (−) value to the selected word line WL_{N}, and may be configured to apply a pass voltage VPASS having a positive (+) value to the unselected word lines WL_{N-1} and WL_{N+1}.

As the program operation is performed, the dipoles of the data storage pattern 132 opposite to the selected word line WL_{N} may be oriented so that anodes are located toward the selected word line WL_{N} and the cathodes are located toward the channel pattern 130, as shown. That is, by the above program operation, the target memory cell corresponding to the selected word line WL_{N} may have a relatively high threshold voltage.

Referring to FIG. 8, an initializing status E may be set by the initializing operation, and at least one program status P1 to P7 may be set by the program operation. As described above, program threshold voltages V_{TH}_1 to V_{TH}_7 of the program statuses P1 to P7 may be higher than the initial threshold voltage V_{TH}_E of the initializing status E.

In some example embodiments, each memory cell may be a multi-level cell (MLC) that stores two or more bits of data. As an example, FIG. 8 shows a case where each memory cell is a triple-level cell (TLC).

For example, after the initializing operation is performed, a first program voltage having a negative (−) value is applied to the selected word line WL_{N}, and a first program operation may be performed on the target memory cell. As the first program operation is performed, the target memory cell may be set to a first program status P1 having a first threshold voltage V_{TH}_1 greater than the initial threshold voltage V_{TH}_E.

Alternatively, for example, after the initializing operation is performed, a second program voltage having a negative (−) value and smaller than the first program voltage is applied to the selected word line WL_{N}, and the second program operation may be performed on the target memory cell. As the second program operation is performed, the target memory cell may be set to a second program status P2 having a second threshold voltage V_{TH}_2 greater than the first threshold voltage V_{TH}_1.

Similarly, the target memory cells may be set to third to seventh program statuses P3 to P7 having third to seventh threshold voltages V_{TH}_3 to V_{TH}_7, respectively.

Referring to FIG. 9, in the programming method of the semiconductor memory device according to some example embodiments, the program operation may use an incremental step pulse erasing (ISPE) scheme.

The ISPE scheme means a scheme in which the negative (−) voltage level of the program voltage V_{PGM} applied to the selected word line WL_{N} is gradually decreased. For example, at the time of the program operation, unit program voltages (V_{PMIN}, V_{PMIN}-ΔV, V_{PMIN}-2ΔV, . . . , V_{PMIN}-nΔV (=V_{PMAX})), which decrease gradually from an initial program voltage V_{PMIN} to a final program voltage V_{PMAX} by a desired (and/or alternatively predetermined) voltage width (ΔV), may be applied repeatedly to the selected word line WL_{N}. Each of the unit program voltages may have a negative (−) value. As an example, the initial program voltage V_{PMIN} may be about −8V, the final program voltage V_{PMAX} may be about −10V, and the voltage width ΔV may be about 0.2V.

In some example embodiments, the ISPE scheme may include application of a verifying voltage VVRF subsequent to each of the unit program voltages. The verifying voltage VVRF may have a positive (+) value. The verifying voltage VVRF may be used to verify the threshold voltage of the memory cell according to each unit program voltage.

As the ISPE scheme is performed, the threshold voltage distribution of each of the program statuses P1 to P7 may be controlled. For example, as shown in FIG. 8, the threshold voltage distribution of each of the program statuses P1 to P7 may be smaller than the threshold voltage distribution of the initializing status E.

In some example embodiments, the initializing operation may utilize an Incremental Step Pulse Programming (ISPP) scheme. The ISPP scheme refers to a scheme in which the positive (+) voltage level of the initializing voltage V_{ERS} applied to the plurality of word lines WL_{N-1}, WL_{N}, and WL_{N+1} is gradually increased. When the ISPP scheme is implemented, the threshold voltage distribution in the initializing status E may be controlled.

As the semiconductor memory device becomes increasingly highly integrated, memory cells including ferroelectric-based data storage elements are being researched. In the memory cells arranged three-dimensionally, the ferroelectric-based data storage elements may be advantageous to reduce the cross-sectional area of the cell string (e.g., the CSTR of FIG. 2).

On the other hand, for the memory cell including the ferroelectric-based data storage elements, the initializing operation may be performed at a low voltage (e.g., negative (−) voltage) and, the program operation may be performed at a high voltage (e.g., positive (+) voltage). As an example, FIG. 10 shows a change in the threshold voltage V_{TH} with an increase in program voltage V_{PGM} having a positive (+) value, for a memory cell initialized with the initializing voltage V_{ERS} having a negative (−) value. However, in this case, an amount of decrease in threshold voltage V_{TH} (hereinafter an ISPP slope S1) for the amount of increase in program voltage V_{PGM} may have a relatively small value (e.g., about 1 or less). The ISPP slope S1 of the small value functions as a disadvantageous factor in terms of the operating voltage, operating speed, and multi-leveling of the memory cell.

In contrast, as explained above, in the programming method of the semiconductor memory device according to some example embodiments, for the memory cell including the ferroelectric-based data storage elements, the initializing operation may be performed at a high voltage (e.g., positive (+) voltage), and the program operation may be performed at a low voltage (e.g., negative (−) voltage). As an example, FIG. 11 shows a change in the threshold voltage V_{TH} with a decrease in the program voltage V_{PGM} having a negative (−) value, for a memory cell that is initialized with an initializing voltage V_{ERS} having a positive (+) value. In this case, an amount of increase in the threshold voltage V_{TH} (hereinafter, an ISPE slope S2) for the amount of decrease in program voltage V_{PGM} may have a relatively larger value (e.g., about 3 or more) than the ISPP slope S1 of FIG. 10. The ISPE slope S2 having a large value may function as an advantageous factor in terms of the operating voltage, operating speed, and multi-leveling of the memory cell. Accordingly, it is possible to provide a semiconductor memory device having improved performance and reliability.

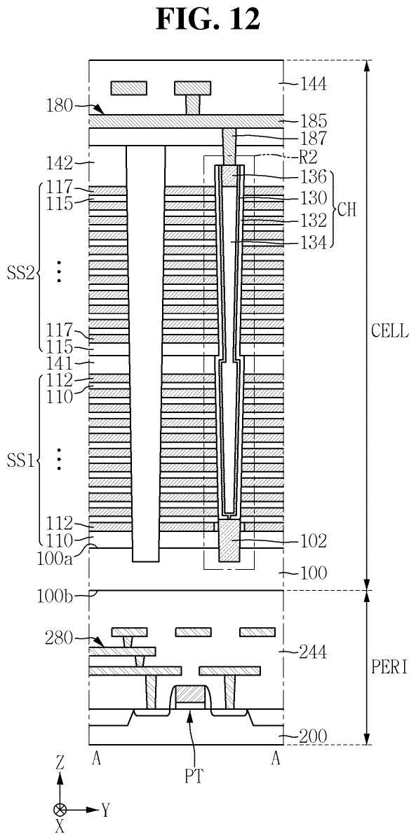

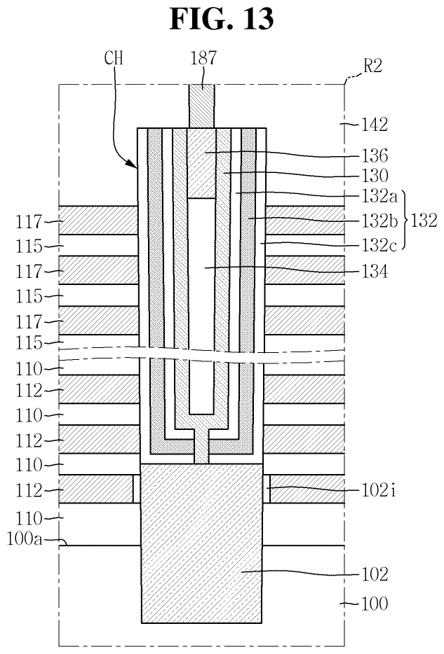

FIG. 12 is a schematic cross-sectional view for explaining a semiconductor memory device according to some example embodiments. FIG. 13 is an enlarged view for explaining a region R2 of FIG. 12. For convenience of explanation, repeated parts of those explained above using FIGS. 1 to 11 will be briefly explained or omitted.

Referring to FIGS. 12 and 13, the semiconductor memory device according to some example embodiments includes a source pattern 102.

The source pattern 102 may be formed on the first substrate 100. The source pattern 102 may be interposed between the first substrate 100 and the channel pattern 130, and between the first substrate 100 and the data storage pattern 132. The source pattern 102 may be electrically connected to the channel pattern 130. For example, one end (e.g., a lower end) of the channel pattern 130 may penetrate the bottom of the data storage pattern 132 and may be in contact with the upper surface of the source pattern 102.

The source pattern 102 may include a conductive material, for example, but not limited to, impurity-doped polysilicon or metal. As an example, the source pattern 102 may include a polysilicon film doped with an N-type impurity (e.g., phosphorus (P) or arsenic (As)). In some example embodiments, the source pattern 102 may be formed from the first substrate 100 by a selective epitaxial growth process. The first substrate 100 and the source pattern 102 may be provided as a common source line (e.g., CSL of FIG. 2) of the semiconductor device according to some example embodiments.

In some example embodiments, the source pattern 102 may be formed to be higher than the upper surface of the lowermost gate electrode disposed at the lowermost part among the first gate electrodes 112. The source pattern 102 may be spaced apart from the lowermost gate electrode by a side insulating film 102i.

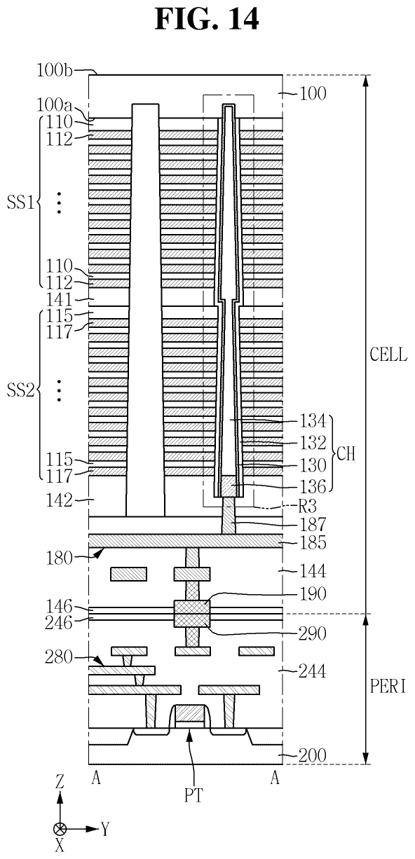

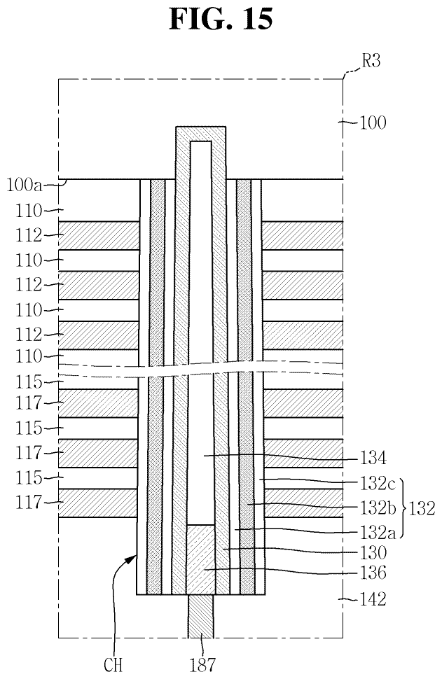

FIG. 14 is a schematic cross-sectional view for explaining a semiconductor memory device according to some example embodiments. FIG. 15 is an enlarged view for explaining a region R3 of FIG. 14. For convenience of explanation, repeated parts of those explained above using FIGS. 1 to 11 will be briefly explained or omitted.

Referring to FIGS. 14 and 15, in the semiconductor memory device according to some example embodiments, the first side 100a of the first substrate 100 is opposite to the peripheral circuit structure PERI.

For example, the semiconductor device according to some example embodiments may be a C2C (chip-to-chip) structure. The C2C structure may mean a structure in which an upper chip including a memory cell structure CELL is manufactured on a first wafer, a lower chip including a peripheral circuit structure PERI is manufactured on a second wafer different from the first wafer, and then, the upper chip and the lower chip are connected to each other by a bonding scheme.

As an example, the bonding scheme may mean a scheme that electrically connects a first bonding metal 190 (and/or a first bonding insulating film 146) formed on the uppermost metal layer of the upper chip and a second bonding metal 290 (and/or a second bonding insulating film 246) formed on the uppermost metal layer of the lower chip to each other. For example, when the first bonding metal 190 and the second bonding metal 290 are formed of copper (Cu), the bonding scheme may be a Cu—Cu bonding scheme. However, this is merely an example, and the first bonding metal 190 and the second bonding metal 290 may, of course, be formed of various other metals such as aluminum (Al) or tungsten (W). However, example embodiments are not limited thereto.

As the first bonding metal 190 and the second bonding metal 290 are bonded, the first wiring structure 180 may be electrically connected to the second wiring structure 280. Accordingly, a plurality of memory cells formed in the cell array region CA may be electrically connected to the peripheral circuit element PT.

Hereinafter, an electronic system including the semiconductor memory device according to various example embodiments will be described with reference to FIGS. 1 to 18.

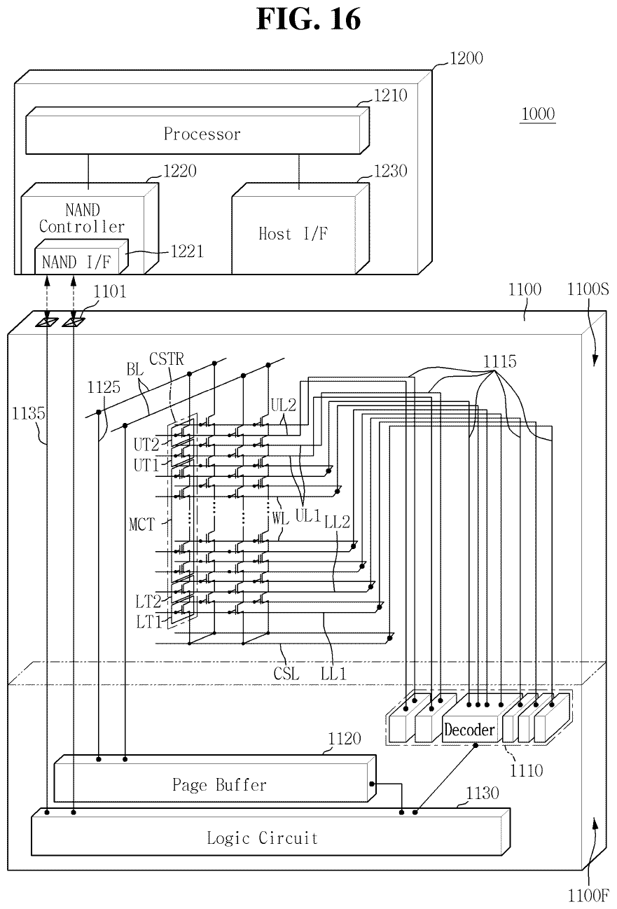

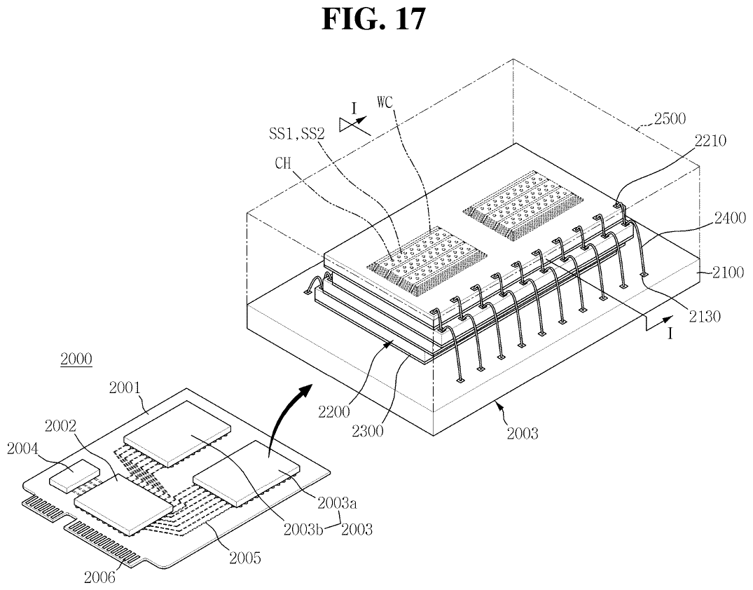

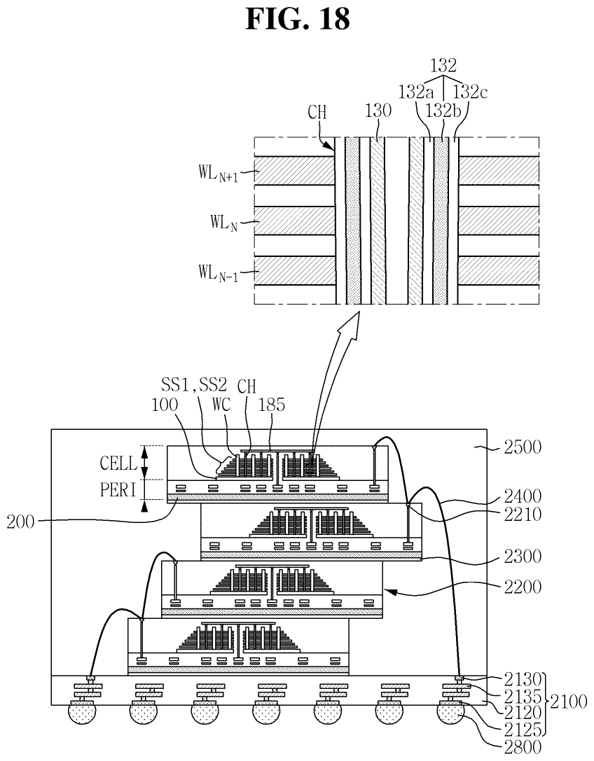

FIG. 16 is an example block diagram for explaining an electronic system according to some example embodiments. FIG. 17 is an example perspective view for explaining the electronic system according to some example embodiments. FIG. 18 is a schematic cross-sectional view taken along I-I of FIG. 17. For convenience of explanation, repeated parts of those explained above using FIGS. 1 to 15 will be briefly explained or omitted.

Referring to FIG. 16, an electronic system 1000 according to some example embodiments may include a semiconductor memory device 1100, and a controller 1200 that is electrically connected to the semiconductor memory device 1100. The electronic system 1000 may be a storage device that includes one or multiple semiconductor memory devices 1100, or an electronic device that includes the storage device. For example, the electronic system 1000 may be a solid state drive (SSD) device, a universal serial bus (USB), a computing system, a medical device or a communication device that includes one or multiple semiconductor memory devices 1100. However, example embodiments are not limited thereto.

The semiconductor memory device 1100 may be a non-volatile memory device (e.g., a NAND flash memory device), and may include, for example, at least one of the semiconductor memory devices explained above using FIGS. 1 to 15. The semiconductor memory device 1100 may include a first structure 1100F, and a second structure 1100S on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1), and a logic circuit 1130 (e.g., the control circuit 37 of FIG. 1). The first structure 1100F may correspond to, for example, the peripheral circuit structure PERI explained above using FIGS. 1 to 15.

The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit lines BL and the common source line CSL. The second structure 1100S may correspond to, for example, the memory cell structure CELL explained above using FIGS. 1 to 15.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be modified variously depending on the embodiments.

In some example embodiments, the upper transistors UT1 and UT2 may include string selection transistors, and the lower transistors LT1 and LT2 may include ground selection transistors. The gate lower lines LL1 and LL2 may be gate electrodes of the lower transistors LT1 and LT2, respectively. The word lines WL may be the gate electrodes of the memory cell transistors MCT, and the gate upper lines UL1 and UL2 may be the gate electrodes of the upper transistors UT1 and UT2, respectively.

In some example embodiments, the lower transistors LT1 and LT2 may include a lower erase control transistor LT1 and a ground selection transistor LT2 that are connected in series. In some example embodiments, the upper transistors UT1 and UT2 may include a string selection transistor UT1 and an upper erase control transistor UT2 that are connected in series. At least one of the lower erase control transistor LT1 and the upper erase control transistor UT1 may be used for an erasing operation that erases data stored in the memory cell transistor MCT, by using a gate induce drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through the first connection wirings 1115 extending from the inside of the first structure 1100F to the second structure 1100S. The bit lines BL may be electrically connected to the page buffer 1120 through second connection wirings 1125 extending from the inside of the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor memory device 1100 may communicate with the controller 1200 through an I/O pad 1101 electrically connected to the logic circuit 1130. The I/O pad 1101 may be electrically connected to the logic circuit 1130 through an I/O connection wiring 1135 extending from the inside of the first structure 1100F to the second structure 1100S.

The controller 1200 may include a processor 1210, a NAND controller 1220, and a host interface 1230. In some example embodiments, the electronic system 1000 may include a plurality of semiconductor memory devices 1100, and in this case, the controller 1200 may control the plurality of semiconductor memory devices 1100.

The processor 1210 may control the operation of the overall electronic system 1000 including the controller 1200. The processor 1210 may operate according to a desired (and/or alternatively predetermined) firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 17 and 18, the electronic system according to some example embodiments may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of fins coupled to an external host. In the connector 2006, the number and placement of the plurality of fins may vary depending on the communication interface between the electronic system 2000 and the external host. In some example embodiments, the electronic system 2000 may communicate with the external host in accordance with any one of interfaces such as universal serial bus (USB), peripheral component interconnect (PCI)-Express, serial advanced technology attachment (SATA), and M-Phy for universal flash storage (UFS). In some example embodiments, the electronic system 2000 may operate by power supplied from the external host through the connector 2006. The electronic system 2000 may further include a power management integrated circuit (PMIC) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on the lower faces of each of the package chips 220, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 16.

In some example embodiments, the connecting structure 2400 may be a bonding wire that electrically connects the I/O pad 2101 and the package upper pads 2130. Therefore, in each of the first semiconductor package 2003a and the second semiconductor package 2003b, the semiconductor chips 2200 may be electrically connected to each other by a bonding wire scheme, and may be electrically connected to the package upper pads 2130 of the package substrate 2100. In some example embodiments, in each of the first semiconductor package 2003a and the second semiconductor package 2003b, the semiconductor chips 2200 may be electrically connected to each other by a connecting structure including a through electrode (Through Silicon Via, TSV) instead of the connecting structure 2400 of the bonding wire scheme.

In some example embodiments, the main controller 2002 and the semiconductor chips 2200 may be included in a single package. In some example embodiments, the main controller 2002 and the semiconductor chips 2200 are mounted on a separate interposer substrate different from the main board 2001, and the main controller 2002 and the semiconductor chips 2200 may be connected to each other by the wiring formed on the interposer substrate.

In some example embodiments, the package substrate 2100 may be a printed circuit board. The package substrate 2100 may include a package substrate body portion 2120, package upper pads 2130 disposed on an upper surface of the package substrate body portion 2120, lower pads 2125 disposed on a lower face of the package substrate body portion 2120 or exposed through the lower face, and inner wirings 2135 that electrically connect the package upper pads 2130 and the lower pads 2125 inside the package substrate body portion 2120. The package upper pads 2130 may be electrically connected to the connecting structures 2400. The lower pads 2125 may be connected to the wiring patterns 2005 of the main board 2001 of the electronic system 2000 through conductive connections 2800, as in FIG. 17.

In the electronic system according to some example embodiments, each of the semiconductor chips 2200 may include the semiconductor memory device described above using FIGS. 1 to 15. For example, each of the semiconductor chips 2200 may include a peripheral circuit structure PERI, and a memory cell structure CELL stacked on the peripheral circuit structure PERI. As an example, the memory cell structure CELL may include the first substrate 100, the stacked structures SS1 and SS2, the channel structure CH, the cutting pattern WC, and the conductive line 185 explained above using FIGS. 1 to 15. Further, as an example, the peripheral circuit structure PERI may include the second substrate 200 and the peripheral circuit element PT explained above using FIGS. 1 to 15.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A programming method of a semiconductor memory device including a plurality of word lines stacked to be spaced apart from each other in a vertical direction;
a channel pattern that extends in the vertical direction and intersects the plurality of word lines; and
a data storage pattern including ferroelectrics between the plurality of word lines and the channel pattern,
the programming method comprising:
performing an initializing operation on a plurality of memory cells corresponding to the plurality of word lines by
applying a positive (+) voltage to the plurality of word lines, or by
applying a negative (−) voltage to the channel pattern; and performing a program operation on a target memory cell corresponding to a selected word line, by
applying a negative (−) program voltage to the selected word line among the plurality of word lines, after performing the initializing operation.

2. The programming method of claim 1,
wherein a threshold voltage of the target memory cell due to the program operation is greater than the threshold voltage of the target memory cell due to the initializing operation.

3. The programming method of claim 1,
wherein the applying of the negative (−) program voltage utilizes an incremental step pulse erasing (ISPE) scheme that gradually reduces a negative (−) voltage level.

4. The programming method of claim 1,
wherein a threshold voltage distribution of the plurality of memory cells due to the program operation is smaller than a threshold voltage distribution of the plurality of memory cells due to the initializing operation.

5. The programming method of claim 1,
wherein the performing of the program operation comprises:
performing a first program operation on the target memory cell, by applying a negative (−) first program voltage to the selected word line, after performing the initializing operation, and
performing a second program operation on the target memory cell, by applying a negative (−) second program voltage smaller than the negative (−) first program voltage to the selected word line, after performing the initializing operation.

6. The programming method of claim 5,
wherein a first threshold voltage of the target memory cell due to the first program operation is greater than an initial threshold voltage of the target memory cell due to the initializing operation, and
a second threshold voltage of the target memory cell due to the second program operation is greater than the first threshold voltage.

7. The programming method of claim 1,
wherein a ratio of an amount of increase in a threshold voltage of the target memory cell with respect to an amount of decrease in the negative (−) program voltage applied to the selected word line is 3 or more.

8. A programming method of a semiconductor memory device including
a plurality of word lines stacked to be spaced apart from each other in a vertical direction;
a channel pattern that extends in the vertical direction and intersects the plurality of word lines; and
a data storage pattern including ferroelectrics between the plurality of word lines and the channel pattern,
the programming method comprising:
performing an initializing operation on a plurality of memory cells corresponding to the plurality of word lines; and
performing a first program operation on a target memory cell corresponding to a selected word line, by
applying a negative (−) first program voltage to the selected word line among the plurality of word lines, after performing the initializing operation,
wherein a first threshold voltage of the target memory cell due to the first program operation is greater than an initial threshold voltage of the target memory cell due to the initializing operation.

9. The programming method of the semiconductor memory device of claim 8,
wherein the performing of the initializing operation comprises applying a positive (+) initializing voltage to the plurality of word lines.

10. The programming method of the semiconductor memory device of claim 9,
wherein the applying of the initializing voltage utilizes an incremental step pulse programming (ISPP) scheme, such that a positive (+) voltage level of the initializing voltage level is gradually increased.

11. The programming method of the semiconductor memory device of claim 8,
wherein the semiconductor memory device further comprises a bit line connected to the channel pattern, and
the performing of the initializing operation comprises applying a negative (−) bit line voltage to the bit line.

12. The programming method of the semiconductor memory device of claim 8,
wherein the applying of the negative (−) first program voltage utilizes an incremental step pulse erasing (ISPE) scheme, such that a negative (−) voltage level of the negative (−) first program voltage is gradually reduced.

13. The programming method of the semiconductor memory device of claim 8,
wherein a threshold voltage distribution of the plurality of memory cells due to the first program operation is smaller than a threshold voltage distribution of the plurality of memory cells due to the initializing operation.

14. The programming method of the semiconductor memory device of claim 8, further comprising:
performing a second program operation on the target memory cell, by applying a negative (−) second program voltage smaller than the negative (−) first program voltage to the selected word line, after performing the initializing operation, and
wherein a second threshold voltage of the target memory cell due to the second program operation is greater than the first threshold voltage.

15. The programming method of the semiconductor memory device of claim 14,
wherein the applying of the negative (−) first program voltage and the applying of the negative (−) second program voltage each utilize an incremental step pulse erasing (ISPE) scheme, such that a negative (−) voltage level of the negative (−) second program voltage is gradually reduced.

16. A semiconductor memory device comprising:
a plurality of word lines stacked to be spaced apart from each other in a vertical direction;
a channel pattern extending in the vertical direction and intersecting the plurality of word lines;
a data storage pattern including ferroelectrics between the plurality of word lines and the channel pattern; and
a control circuit electrically connected to the plurality of word lines and the channel pattern,
wherein the control circuit is configured to
perform an initializing operation on a plurality of memory cells corresponding to the plurality of word lines by
applying a positive (+) voltage to the plurality of word lines, or by
applying a negative (−) voltage to the channel pattern, and
perform a program operation on a target memory cell corresponding to a selected word line, by
applying a negative (−) program voltage to the selected word line among the plurality of word lines, after performing the initializing operation.

17. The semiconductor memory device of claim 16,
wherein a threshold voltage of the target memory cell due to the program operation is greater than the threshold voltage of the target memory cell due to the initializing operation.

18. The semiconductor memory device of claim 16,
wherein the control circuit is configured to apply the negative (−) program voltage, by utilizing an incremental step pulse erasing (ISPE) scheme that gradually reduces a negative (−) voltage level.

19. The semiconductor memory device of claim 16,
wherein the control circuit is configured to apply a positive (+) voltage to the plurality of word lines, by utilizing an incremental step pulse programming (ISPP) scheme that gradually increases a positive (+) voltage level.

20. The semiconductor memory device of claim 16, further comprising:
a bit line connected to the channel pattern,
wherein the control circuit is configured to apply a negative (−) voltage to the bit line.
